(19) United States
(12) Patent Application Publication
(10) Pub. No.: US 2026/0354199 A1
(43) Pub. Date: Nov. 5, 2026

(54) PROVIDING RADIO FREQUENCY SHIELDING BETWEEN SEMICONDUCTOR DIES

(71) Applicant: Silicon Laboratories Inc., Austin, TX (US)

(72) Inventors: Lyric Jackson, Pflugerville, TX (US); Jean Miller-Reyes, Cedar Park, TX (US); Eric Radza, Bee Cave, TX (US); Nancy Fermin, Austin, TX (US); Sheila Marie Galang Letun, Singapore (SG); Geunjong Baek, Singapore (SG); Ricky Jonathan Tulolo, Singapore (SG)

(21) Appl. No.: 19/194,322

(22) Filed: Apr. 30, 2025

(51) Int. Cl. H10W 42/20; H10W 70/40; H10W 72/00; H10W 90/00

(52) U.S. Cl. CPC H10W 42/20; H10W 90/00; H10W 70/40; H10W 72/865; H10W 72/884; H10W 90/734; H10W 90/752; H10W 90/756

(57) ABSTRACT

In one aspect, an apparatus includes: a first semiconductor die having first circuitry and adapted to a substrate; a spacer die adapted above the first semiconductor die; and a second semiconductor die having second circuitry and adapted above the spacer die. The spacer die is to shield electromagnetic interference from at least a first one of the first semiconductor die or the second semiconductor die from radio frequency (RF) circuitry of a second one of the first semiconductor die or the second semiconductor die.

### BACKGROUND

As semiconductor technology advances, it is possible to incorporate multiple dies within a single integrated circuit (IC) package. While this can provide additional functionality for a given integrated circuit, there remain difficulties in manufacturing and implementation. This is especially so when one of the dies has radio frequency (RF) circuitry. In this situation, electrical signaling in the other die can cause interference within the RF circuitry. One possible solution when the other die is much smaller than the die having the RF circuitry is to locate the other die away from the RF circuitry, such that this interference can at least be reduced. However, when the dies are of substantially equal size, it is not possible to locate the interfering die in this manner to avoid interference with the RF circuitry.

### SUMMARY OF INVENTION

In one aspect, an apparatus includes: a first semiconductor die comprising first circuitry and adapted to a substrate; a spacer die adapted above the first semiconductor die; and a second semiconductor die comprising second circuitry and adapted above the spacer die. The spacer die is to shield electromagnetic interference from at least a first one of the first semiconductor die or the second semiconductor die from radio frequency (RF) circuitry of a second one of the first semiconductor die or the second semiconductor die.

In one implementation, the first circuitry of the first semiconductor die includes the RF circuitry comprising at least one wireless transceiver. The first semiconductor die may be a system on chip having the at least one wireless transceiver and at least one core. The second circuitry of the second semiconductor die may include memory circuitry. At least a portion of the spacer die and at least a portion of the second semiconductor die are adapted above the RF circuitry of the first semiconductor die.

In an implementation, at least one surface of the spacer die includes a conductive material. The spacer die may be another semiconductor die having the at least one surface comprising aluminum. The spacer die may be coupled to at least one ground node of the substrate via at least one bond wire. The second semiconductor die may be coupled to the first semiconductor die via a plurality of bond wires.

In an implementation, the apparatus further includes: a first adhesive material to adapt the spacer die to the first semiconductor die; and a second adhesive material to adapt the second semiconductor die to the spacer die.

In one implementation, the apparatus also may include: a second spacer die adapted above the second semiconductor die; and a third semiconductor die comprising third circuitry and adapted above the second spacer die. The second spacer die may be configured to shield electromagnetic interference from at least the second semiconductor die from RF circuitry of the third semiconductor die.

In another aspect, a method includes: adapting a first semiconductor die comprising first circuitry to a substrate; adapting a spacer die above the first semiconductor die; and adapting a second semiconductor die comprising second circuitry above the spacer die. The spacer die may be configured to shield electromagnetic interference from at least a first one of the first semiconductor die or the second semiconductor die from RF circuitry of a second one of the first semiconductor die or the second semiconductor die.

In one implementation, the method further includes: attaching a first plurality of bond wires between the first semiconductor die and the substrate; attaching at least one bond wire between a conductive portion of the spacer die to a ground node of the substrate; and attaching a second plurality of bond wires between the first semiconductor die and the second semiconductor die.

In an implementation, adapting the first semiconductor die to the substrate comprises adapting the first semiconductor die to the substrate comprising a lead frame using a first adhesive material. The method also may include curing the first adhesive material. The method may also include after curing the first adhesive material, attaching a first plurality of bond wires between the first semiconductor die and the lead frame.

In an implementation, the method further comprises: adapting the second semiconductor die above the spacer die using a second adhesive material; curing the second adhesive material; and thereafter attaching at least one bond wire between a conductive portion of the spacer die to a ground node of the lead frame and attaching a second plurality of bond wires between the first semiconductor die and the second semiconductor die.

In yet another aspect, an integrated circuit package includes: a lead frame; a first semiconductor die adapted to the lead frame, the first semiconductor die comprising at least one RF transceiver to transmit and receive RF signals; a spacer die adapted to the first semiconductor die, the spacer die comprising at least one conductive surface to shield electromagnetic interference from the at least one RF transceiver; and a second semiconductor die comprising second circuitry and adapted above the spacer die.

In one implementation, the integrated circuit package further includes: a plurality of first bond wires to couple pads of the first semiconductor die to pads of the second semiconductor die; and at least one second bond wire to couple the at least one conductive surface of the second semiconductor die to at least one pad of the lead frame, the at least one pad of the lead frame to be coupled to a ground voltage.

In an implementation, the integrated circuit package further includes: a first adhesive material to adapt the spacer die to the first semiconductor die; and a second adhesive material to adapt the second semiconductor die to the spacer die.

### BRIEF DESCRIPTION OF THE DRAWINGS

FIG. 1 is an isometric view of an exposed IC package in accordance with an embodiment.

FIG. 2 is a cross-sectional view of an integrated circuit package in accordance with an embodiment.

FIG. 3 is a top view of an IC package in accordance with an embodiment.

FIG. 4 is a flow diagram of a method in accordance with an embodiment.

FIG. 5 is a block diagram of a representative integrated circuit in accordance with an embodiment.

FIG. 6 is a block diagram of a system in accordance with an embodiment.

### DETAILED DESCRIPTION

In various embodiments, a stacked die configuration of an integrated circuit (IC) package can be realized in a manner to provide shielding to prevent electromagnetic activity due to electrical signaling occurring on one die from interfering with processing of radio frequency (RF) signals within RF circuitry of another die. While a particular implementation of given dies having various functionality and arranged in a certain stacked manner is described, understand that embodiments are not limited in this regard. That is, in other embodiments other stacked die configurations with dies having different functionality and different ordering of the stacked dies are possible, while still achieving the benefits of the shielding described herein. Also, while the implementation described herein involves a stacked die configuration having two semiconductor dies with an intervening spacer die, it is possible for there to be multiple spacer dies, each providing shielding for at least one other die.

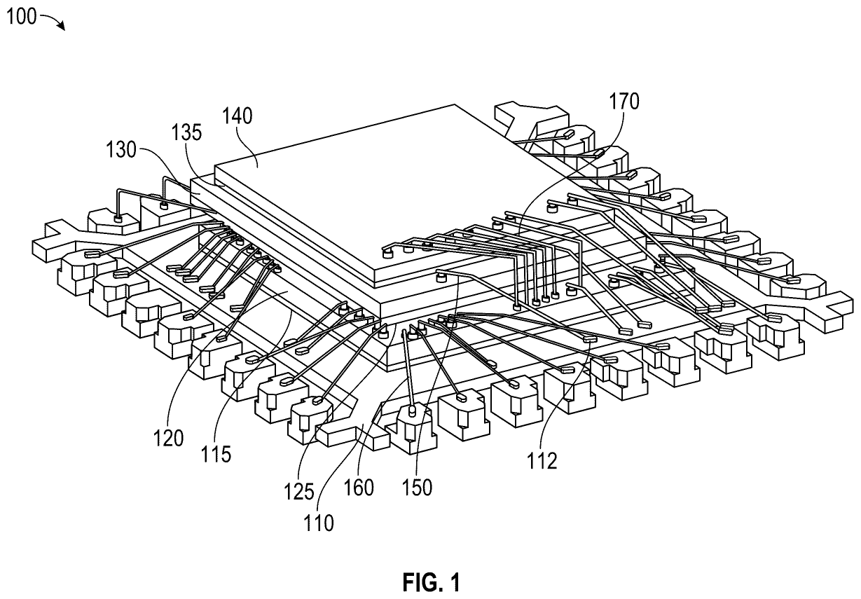

Referring to FIG. 1, shown is an isometric view of an exposed IC package in accordance with an embodiment. As shown in FIG. 1, IC package 100 includes a lead frame 110 to which a first die 120 is adapted. Understand that in other implementations, a different type of substrate may be used in place of lead frame 110, or a laminate packaging base may be used. In the embodiment of FIG. 1, first semiconductor die 120 (hereafter ‘semiconductor die’ or just ‘die’) may be implemented as a wireless system on chip (SoC) having RF circuitry. For example, first die 120 may be a multi-protocol wireless SoC that can communicate according to multiple wireless protocols, such as Wi-Fi, Bluetooth, Bluetooth Low Energy, Matter, Thread, and/or IEEE 802.15.4, among others. In addition, first die 120 also may include one or more cores, along with potentially other circuitry such as sensors, actuators or so forth. As one example, first die 120 may provide for Internet of Things (IoT) functionality.

As shown, first die 120 adapts to lead frame 110 via an adhesive material 115. Depending upon implementation, adhesive material 115 may be implemented as an epoxy or a film. In turn, a spacer die 130 is adapted on first die 120. Spacer die 130 may be implemented as a silicon or other semiconductor die that has conductive material on at least one surface thereof. In some implementations, spacer die 130 may be formed as a thin laminated substrate having foil surfaces of a given conductive material (e.g., aluminum, copper or so forth). In a particular embodiment, spacer die 130 may be implemented with a fully covered sputtered aluminum layer adhered to a silicon die so that it may act as an RF shield. Stated another way, when adapted in a system and spacer die 130 is coupled to a given ground or other reference voltage node, spacer die 130 forms a grounded isolation barrier to prevent electromagnetic energy from interfering with RF processing occurring in first die 120. Spacer die 130 may be adapted onto first die 120 via a second adhesive material 125, e.g., a given epoxy or film.

A second semiconductor die 140 is adapted above spacer die 130. Second die 140 may be adapted onto spacer die 130 via a third adhesive material 135, e.g., a given epoxy or film. In an embodiment, second die 140 may be implemented as a memory device such as a flash memory. In other cases, second die 140 may be implemented as another type of memory such as a random access memory (e.g., a pseudo static random access memory). In yet other implementations, second die 140 may include different circuitry, such as another type of SoC, and in some cases second die 140 also may include RF circuitry.

To shield RF circuitry included in first die 120 from interference caused by electrical activity in second die 140, a conductive material of spacer die 130 electrically couples to a ground or other reference voltage node. More specifically as shown in FIG. 1, via a bond wire 150, a top surface of spacer die 130 electrically couples to a ground pad 112 present on lead frame 110. Although a single bond wire is shown for ease of illustration in FIG. 1, understand that a plurality of bond wires may be provided to electrically couple the conductive material of spacer die 130 to one or more ground nodes that may be present on lead frame 110. This coupling of the conductive surface of spacer die 130 to ground pad 112 of lead frame 110, which is further coupled to a ground voltage (e.g., via connection through a contact of the IC package to a ground node of a printed circuit board that in turn couples to a ground voltage or other reference voltage) causes spacer die 130 to act as an RF shield to block electromagnetic radiation originating in second die 140 from interfering with RF circuitry of first die 120.

As further shown, a plurality of bond wires couple to pads of first die 120 to enable interconnection to supply voltages, ground connections and off-chip connections through pads of lead frame 110. For ease of illustration in FIG. 1, only a single such bond wire is enumerated as bond wire 160. As also shown in FIG. 1, another plurality of bond wires are provided to couple second die 140 to first die 120. Illustrated in FIG. 1, only a single such bond wire is enumerated as bond wire 170. Although shown with this particular implementation in the embodiment of FIG. 1, understand that many variations and alternatives are possible. For example, in other implementations the ordering of semiconductor dies may differ, with a die having RF circuitry present at a top of a stack and separated from an underlying semiconductor die of the stack via at least one spacer die.

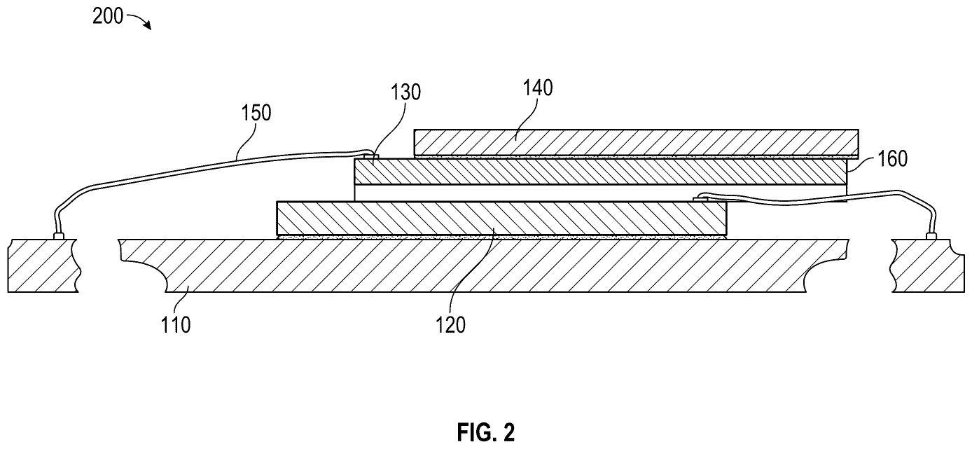

Referring now to FIG. 2, shown is a cross-sectional view of an integrated circuit package in accordance with an embodiment. As shown in FIG. 2, IC package 200 includes a stacked die implementation. Note that the same reference numerals are used in FIG. 2 to identify the same components as in FIG. 1. Thus as seen, an IC package 200 is arranged with a lead frame 110, on which a first semiconductor die 120 is adapted. In turn, a spacer die 130 is adapted above first semiconductor die 120 and a second semiconductor die 140 is adapted above spacer die 130. As further shown in FIG. 2, example bond wire 150 couples between spacer die 130 and lead frame 110 (and more specifically to a pad of lead frame 110 that in turn couples to a ground voltage when IC package 200 is adapted on a circuit board). Also illustrated in FIG. 2 is a bond wire 160, which is an exemplary bond wire that couples between a pad of first semiconductor die 120 and a pad of lead frame 110. Although not shown in this cross-sectional view, understand that there may be multiple such bond wires, both coupling between spacer die 130 and pads of lead frame 110 (possibly) and multiple bond wires coupling pads of first semiconductor die 120 to pads of lead frame 110. Although not shown in FIG. 2, first semiconductor die 120 and second semiconductor die 140 may couple together via a plurality of bond wires.

In an embodiment, first semiconductor die 120 and second semiconductor die 140 both may have a thickness of between approximately 100-150 microns (μm). In turn, spacer die 130 may have a thickness of between approximately 50-100 μm. One or both sides of spacer die 130 may have a conductive surface, which in some implementations may be an aluminum layer of approximately 1 μm that may be deposited via given deposition process such as sputtering, plating or so forth.

Also shown in FIG. 2 but not specifically enumerated is adhesive material to adapt first semiconductor die 120 to lead frame 110, as well as additional adhesive layers for adapting spacer die 130 to first semiconductor die 120 and adapting second semiconductor die 140 to spacer die 130. Such adhesive material may be a given film or epoxy and may have a thickness of approximately 25 microns in an implementation. Although shown at this high level in the embodiment of FIG. 2, many variations and alternatives are possible.

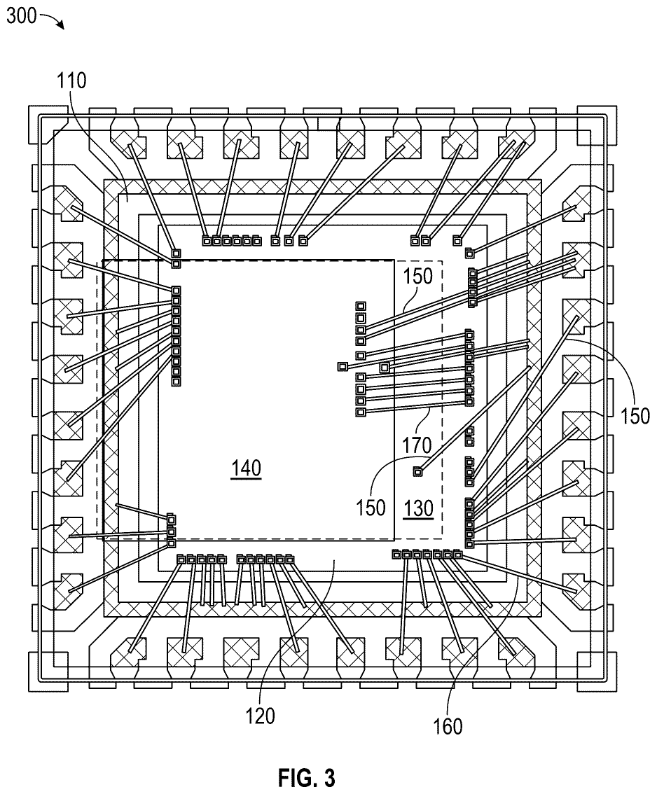

Referring now to FIG. 3, shown is a top view of an IC package in accordance with an embodiment. As shown in FIG. 3, IC package 300 may include the same stack of dies, namely first semiconductor die 120, spacer die 130 and second semiconductor die 140. In the top view of FIG. 3, note that second semiconductor die 140 has a smaller area than spacer die 130, which itself has a smaller area than first semiconductor die 120. Of course other dimensions are possible, and it is possible for second semiconductor 140 to have a greater area than first semiconductor die 110; however spacer die 130 may be sized to have at least as large an area as second semiconductor die 140 to effectively act as a shield.

FIG. 3 further illustrates exemplary bond wires. As shown a bond wire 160 is an example of a bond wire that couples between first die 120 and lead frame 110. Bond wire 150 couples between spacer die 130 and lead frame 110, and bond wires 170 couple second semiconductor die 140 to first semiconductor die 120. Of course additional bond wires may further couple in similar manner.

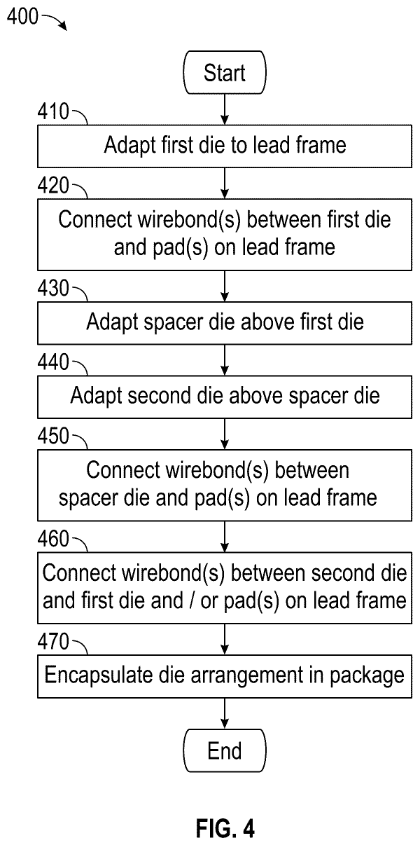

Referring now to FIG. 4, shown is a flow diagram of a method in accordance with an embodiment. As shown in FIG. 4, method 400 is a method for assembling an IC package having shielding as described herein.

As shown, method 400 begins by adapting a first semiconductor die to a lead frame (block 410). In one embodiment, the first semiconductor die, which may be a multi-protocol wireless SoC, can be adapted to the lead frame using a given adhesive material such as epoxy or adhesive film, and a curing process can be performed. Next at block 420, wire bonds may be connected between the first semiconductor die and pads on the lead frame. These wire bonds form electrical connections for providing supply voltages, ground voltages, communication paths and so forth.

Next at block 430, a spacer die is adapted above the first semiconductor die. As described above, the spacer die may have at least one conductive surface so that it may act as an RF shield. The spacer die may be adapted to the first semiconductor die via a given adhesive material, and can be cured. In one embodiment, a conformal adhesive layer such as a die-attach film adhesive may be used. Thereafter at block 440, a second semiconductor die is adapted above the spacer die. This second semiconductor die may include a variety of circuitry. In some cases the second semiconductor die may be a memory device such as a flash memory; in other cases it may be another SoC, and in certain implementations it may also include RF circuitry. Note that in some cases, the first semiconductor die and the second semiconductor die may be of different entities, such as a multi-protocol SoC of a first designer and a second semiconductor die of a customer of that designer. In this way, a stacked die configuration of an IC package is realized to include a customer-specific semiconductor die for a given application. For example, an IoT IC package can include such semiconductor dies of different entities.

Still referring to FIG. 4, at block 450 at least one wire bond may be connected between the spacer die and at least one pad on the lead frame. In various embodiments, there can be a single wire bond to couple the conductive material to a given ground pad on the lead frame to enable the spacer die to act as RF shield. Note that this ground pad on the lead frame, when the IC package is adapted in a system, will be connected to a given ground voltage.

Still with reference to FIG. 4, at block 460 wire bonds may be connected between the second semiconductor die and the first semiconductor die. These wire bonds form electrical connections for providing supply voltages, ground voltages, communication paths and so forth.

Finally with further reference to FIG. 4, at block 470 the stacked die arrangement is encapsulated in IC package using a given encapsulant material such as a molding compound of a fabricated lid assembly. Understand that additional operations in assembling the IC package may occur, such as completing the packaging, performing various functional testing and so forth.

Although shown at this high level in the embodiment of FIG. 4, understand that many variations and alternatives are possible. For example, while a given order of operations has been discussed, it is possible to differently perform the operations. For example, stacking of a first semiconductor die to a lead frame and associated wire bond connections may occur separately from adapting another semiconductor die to a spacer die. Thereafter another adapting process can be performed to adapt the spacer die/semiconductor die combination to the first semiconductor die. Then various wire bonding operations can be performed before finally encapsulating the resulting stacked die arrangement into the IC package.

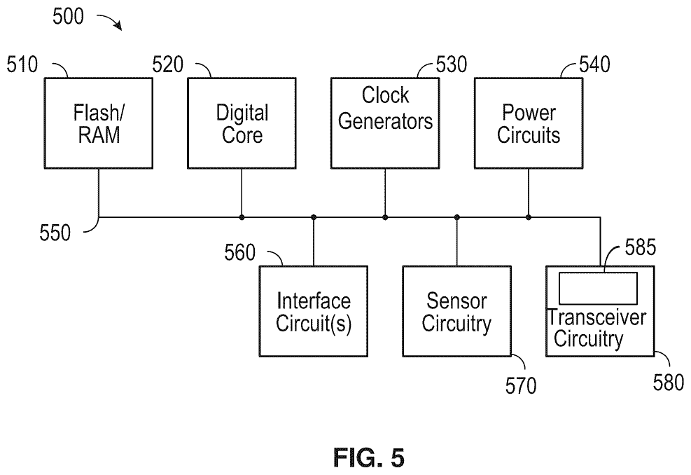

Embodiments can be implemented in many different environments. Referring now to FIG. 5, shown is a block diagram of a representative integrated circuit 500 that can be manufactured in a stacked die relationship as described herein. In the embodiment shown in FIG. 5, integrated circuit 500 may be, e.g., a single or multi-protocol wireless SoC having a wireless transceiver that may operate according to one or more wireless protocols (e.g., WLAN-OFDM, WLAN-DSSS, Bluetooth, among others), or other device that can be used in a variety of use cases, including sensing, metering, monitoring, embedded applications, communications, applications and so forth, and which may be particularly adapted for use in an IoT device.

In the embodiment shown, integrated circuit 500 includes a memory system 510 which in an embodiment may include a non-volatile memory such as a flash memory and volatile storage, such as RAM. In an embodiment, this non-volatile memory may be implemented as a non-transitory storage medium that can store instructions and data. Memory system 510 may be implemented on a first semiconductor die of a stacked die arrangement.

Memory system 510 couples via a bus 550 to a digital core 520, which may include one or more cores and/or microcontrollers that act as a main processing unit of the integrated circuit. In turn, transceiver circuitry 580 may be provided to enable transmission and receipt of wireless signals, e.g., according to one or more of a local area or wide area wireless communication scheme, such as Zigbee, Bluetooth, IEEE 802.11, IEEE 802.15.4, cellular communication or so forth. As shown, transceiver circuitry 580 includes RF front end circuitry 585 to interface with an off-chip antenna. In embodiments herein, digital core 520 and transceiver circuitry 580 may be implemented on a second semiconductor die of the stacked die arrangement. And understand that a spacer die (not shown in FIG. 5) that acts as an RF shield may be interposed between these first and second dies.

As further shown in FIG. 5, digital core 520 may couple to clock generators 530 which may provide one or more phase locked loops or other clock generator circuitry to generate various clocks for use by circuitry of the IC.

As further illustrated, IC 500 further includes power circuitry 540, which may include one or more voltage regulators. Additional circuitry may optionally be present depending on particular implementation to provide various functionality and interaction with external devices. Such circuitry may include interface circuitry 560 which may provide interface with various off-chip devices, sensor circuitry 570 which may include various on-chip sensors including digital and analog sensors to sense desired signals, such as for a metering application or so forth. Understand while shown with this high level view, many variations and alternatives are possible.

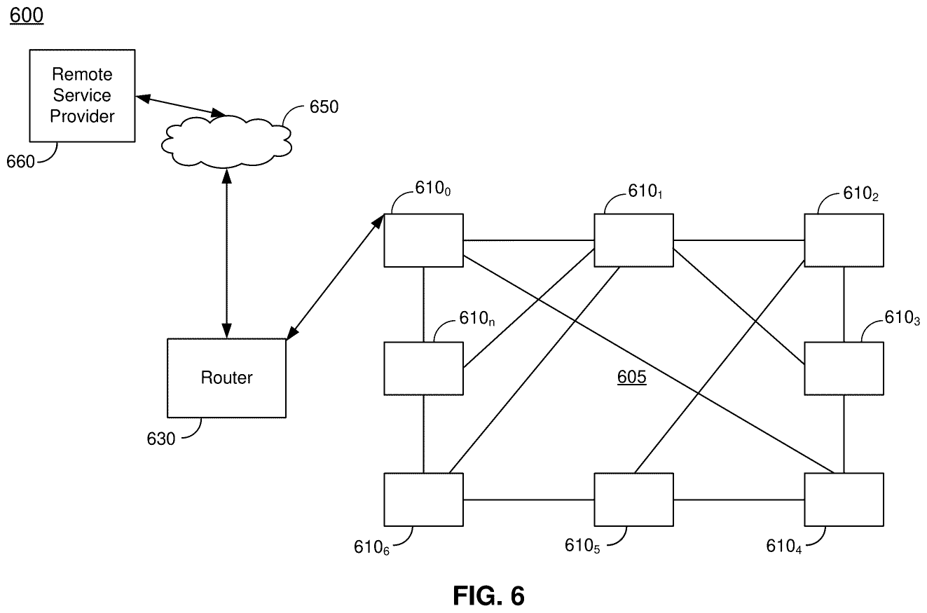

Referring now to FIG. 6, shown is a high level diagram of a network in accordance with an embodiment. As shown in FIG. 6, a network 600 includes a variety of devices, including smart devices such as IoT devices, routers and remote service providers. In the embodiment of FIG. 6, a mesh network 605 may be present, e.g., in a building having multiple IoT devices 610₀₋ₙ. Such IoT devices may include single or multi-protocol wireless SoCs having stacked die arrangements as described herein. As shown, at least one IoT device 610 couples to a router 630 that in turn communicates with a remote service provider 660 via a wide area network 650, e.g., the internet. In an embodiment, remote service provider 660 may be a backend server of a utility that handles communication with IoT devices 610. Understand while shown at this high level in the embodiment of FIG. 6, many variations and alternatives are possible.

While the present disclosure has been described with respect to a limited number of implementations, those skilled in the art, having the benefit of this disclosure, will appreciate numerous modifications and variations therefrom. It is intended that the appended claims cover all such modifications and variations.

What is claimed is:

1. An apparatus comprising:
a first semiconductor die comprising first circuitry and adapted to a substrate;
a spacer die adapted above the first semiconductor die; and
a second semiconductor die comprising second circuitry and adapted above the spacer die, wherein the spacer die is to shield electromagnetic interference from at least a first one of the first semiconductor die or the second semiconductor die from radio frequency (RF) circuitry of a second one of the first semiconductor die or the second semiconductor die.

2. The apparatus of claim 1, wherein the first circuitry of the first semiconductor die comprises the RF circuitry comprising at least one wireless transceiver.

3. The apparatus of claim 2, wherein the first semiconductor die comprises a system on chip comprising the at least one wireless transceiver and at least one core.

4. The apparatus of claim 3, wherein the second circuitry of the second semiconductor die comprises memory circuitry.

5. The apparatus of claim 2, wherein at least a portion of the spacer die and at least a portion of the second semiconductor die are adapted above the RF circuitry of the first semiconductor die.

6. The apparatus of claim 1, wherein at least one surface of the spacer die comprises a conductive material.

7. The apparatus of claim 6, wherein the spacer die comprises another semiconductor die having the at least one surface comprising aluminum.

8. The apparatus of claim 1, wherein the spacer die is coupled to at least one ground node of the substrate via at least one bond wire.

9. The apparatus of claim 8, wherein the second semiconductor die is coupled to the first semiconductor die via a plurality of bond wires.

10. The apparatus of claim 1, further comprising:
a first adhesive material to adapt the spacer die to the first semiconductor die; and
a second adhesive material to adapt the second semiconductor die to the spacer die.

11. The apparatus of claim 1, further comprising:
a second spacer die adapted above the second semiconductor die; and
a third semiconductor die comprising third circuitry and adapted above the second spacer die, wherein the second spacer die is to shield electromagnetic interference from at least the second semiconductor die from RF circuitry of the third semiconductor die.

12. A method comprising:
adapting a first semiconductor die comprising first circuitry to a substrate;
adapting a spacer die above the first semiconductor die; and
adapting a second semiconductor die comprising second circuitry above the spacer die, wherein the spacer die is to shield electromagnetic interference from at least a first one of the first semiconductor die or the second semiconductor die from radio frequency (RF) circuitry of a second one of the first semiconductor die or the second semiconductor die.

13. The method of claim 12, further comprising:
attaching a first plurality of bond wires between the first semiconductor die and the substrate;
attaching at least one bond wire between a conductive portion of the spacer die to a ground node of the substrate; and
attaching a second plurality of bond wires between the first semiconductor die and the second semiconductor die.

14. The method of claim 12, wherein adapting the first semiconductor die to the substrate comprises adapting the first semiconductor die to the substrate comprising a lead frame using a first adhesive material.

15. The method of claim 14, further comprising curing the first adhesive material.

16. The method of claim 15, further comprising after curing the first adhesive material, attaching a first plurality of bond wires between the first semiconductor die and the lead frame.

17. The method of claim 16, further comprising:
adapting the second semiconductor die above the spacer die using a second adhesive material;
curing the second adhesive material; and
thereafter attaching at least one bond wire between a conductive portion of the spacer die to a ground node of the lead frame and attaching a second plurality of bond wires between the first semiconductor die and the second semiconductor die.

18. An integrated circuit package comprising:
a lead frame;
a first semiconductor die adapted to the lead frame, the first semiconductor die comprising at least one radio frequency (RF) transceiver to transmit and receive RF signals;
a spacer die adapted to the first semiconductor die, the spacer die comprising at least one conductive surface to shield electromagnetic interference from the at least one RF transceiver; and
a second semiconductor die comprising second circuitry and adapted above the spacer die.

19. The integrated circuit package of claim 18, further comprising:
a plurality of first bond wires to couple pads of the first semiconductor die to pads of the second semiconductor die; and
at least one second bond wire to couple the at least one conductive surface of the second semiconductor die to at least one pad of the lead frame, the at least one pad of the lead frame to be coupled to a ground voltage.

20. The integrated circuit package of claim 18, further comprising:
a first adhesive material to adapt the spacer die to the first semiconductor die; and
a second adhesive material to adapt the second semiconductor die to the spacer die.
